(19) United States
(12) Patent Application Publication
(10) Pub. No.: US 2022/0139737 A1
(43) Pub. Date: May 5, 2022

(54) TEMPERATURE SENSOR, HEATER UNIT, AND SUBSTRATE PROCESSING APPARATUS

(71) Applicant: KOKUSAI ELECTRIC CORPORATION, Tokyo (JP)

(72) Inventors: Tokunobu AKAO, Toyama-shi (JP); Tetsuya KOSUGI, Toyama-shi (JP)

(73) Assignee: KOKUSAI ELECTRIC CORPORATION, Tokyo (JP)

(21) Appl. No.: 17/513,354

(22) Filed: Oct. 28, 2021

(30) Foreign Application Priority Data
Oct. 29, 2020 (JP) 2020-181250

(51) Int. Cl. H01L 21/67; G05D 23/19; H01L 21/673

(52) U.S. Cl. CPC H01L 21/67109; H01L 21/67303; G05D 23/1931; H01L 21/67248

(57) ABSTRACT

There is provided a configuration installed on a mount provided with an opening, that includes a main body connected to the mount to penetrate the opening while providing a micro space; a first positioner attached to a side of a leading end portion of the main body with respect to the mount; and a second positioner attached to a side of a tail end portion of the main body with respect to the mount, wherein the main body is movable within a range determined by the micro space, the first positioner, and the second positioner.

### CROSS-REFERENCE TO RELATED APPLICATION

This application is based upon and claims the benefit of priority from Japanese Patent Application No. 2020-181250, filed on Oct. 29, 2020, the entire contents of which are incorporated herein by reference.

### TECHNICAL FIELD

The present disclosure relates to a temperature sensor, a heater unit, and a substrate processing apparatus.

### BACKGROUND

In the manufacture of semiconductor devices, a batch-type heat treatment apparatus that treats wafers (hereinafter, also referred to as substrates) has been widely used. For example, according to the related art, in a process furnace in a heat treatment apparatus of this type, a substrate holder (hereinafter, also referred to as a boat) in which a plurality of substrates are mounted is inserted from below into substantially a cylindrical reaction tube with its upper end closed and its lower end opened, and the wafers on the boat is heat-treated by a heating mechanism (hereinafter, also referred to as a heater) provided to surround an outside of the reaction tube.

Further, in the above-mentioned heat treatment apparatus, a thermocouple (hereinafter, also referred to as a heater thermocouple or a first thermocouple (first temperature sensor)) is disposed in the vicinity of the heater to measure a temperature on a heating side, a thermocouple (also referred to as a cascade thermocouple or a second thermocouple (second temperature sensor)) is disposed in the vicinity of the wafers or the reaction tube to measure a temperature of an object to be heated, and the heater is feedback-controlled based on the measured temperatures thereof. However, when the temperature of the heater rises during the operation of the above-mentioned heat treatment apparatus, the thermocouple (the first temperature sensor) disposed in the vicinity of the heater may be damaged due to a thermal stress caused by thermal expansion of members in the vicinity of the heater.

### SUMMARY

Some embodiments of the present disclosure provide a technique capable of measuring the temperature of a heater without being damaged even if the temperature of the heater becomes high.

According to one embodiment of the present disclosure, there is provided a configuration installed on a mount provided with an opening, that includes: a main body connected to the mount to penetrate the opening while providing a micro space; a first positioner attached to a side of a leading end portion of the main body with respect to the mount; and a second positioner attached to a side of a tail end portion of the main body with respect to the mount, wherein the main body is movable within a range determined by the micro space, the first positioner, and the second positioner.

### BRIEF DESCRIPTION OF DRAWINGS

The accompanying drawings, which are incorporated in and constitute a part of the specification, illustrate embodiments of the present disclosure.

FIG. 1 is a plane view of a process furnace of a substrate processing apparatus according to an embodiment of the present disclosure.

FIG. 2 is a plane view of a process furnace of a substrate processing apparatus according to an embodiment of the present disclosure.

FIG. 3 shows an example of a configuration of a temperature control system according to an embodiment of the present disclosure.

FIG. 4 shows an example of temperature change characteristics in a process furnace at each procedure of process performed by a substrate processing apparatus according to an embodiment of the present disclosure.

FIG. 5 shows an example of an apparatus controller configuration according to an embodiment of the present disclosure.

FIG. 6 is an external view of a thermocouple (temperature sensor) according to an embodiment of the present disclosure.

FIG. 7 shows an example of installation of a thermocouple (temperature sensor) in a process furnace of a substrate processing apparatus according to an embodiment of the present disclosure.

FIG. 8 shows an example of a cross section of a main part of a thermocouple (temperature sensor) according to an embodiment of the present disclosure.

FIG. 9 shows an example of a cross section of a leading end portion of a thermocouple (temperature sensor) according to an embodiment of the present disclosure.

FIG. 10 shows an example of a connection part of thermocouple (temperature sensor) according to an embodiment of the present disclosure.

FIG. 11 is a view showing an example when thermocouple (temperature sensor) according to an embodiment of the present disclosure is heat-treated.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A substrate processing apparatus according to an embodiment of the present disclosure will be described with reference to the drawings. However, in the following description, the same constituent elements may be denoted by the same reference numerals, and explanation thereof may be omitted. In addition, in order to clarify explanation, the drawings may schematically show width, thickness, shape, etc. of each part as compared with actual aspects, but this is just an example and does not limit interpretation of the present disclosure.

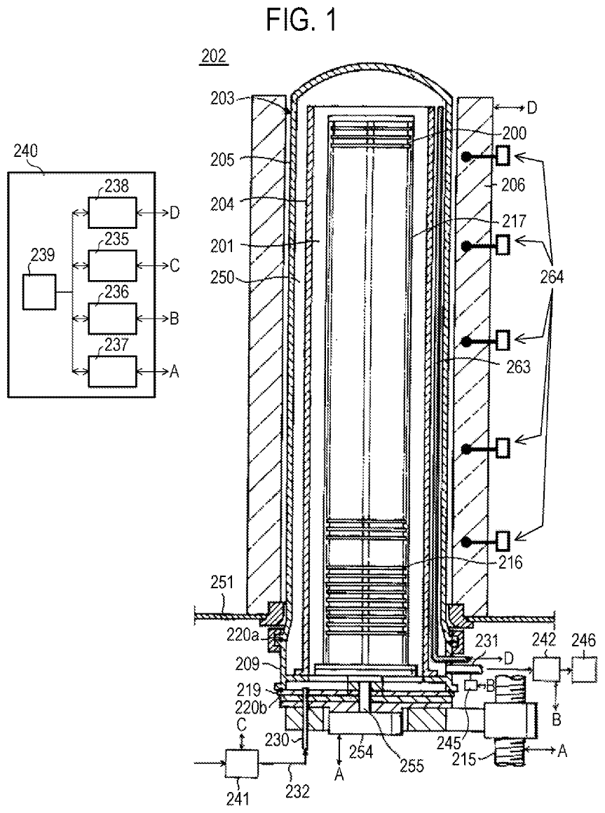

FIG. 1 schematically shows a configuration of a process furnace 202 of a substrate processing apparatus, which is illustrated as a longitudinal sectional view. As shown in FIG. 1, the process furnace 202 has a heater 206 as a heating mechanism (a heater unit). The heater 206 has a cylindrical shape and is supported by a heater base 251 as a support plate to be vertically installed.

A process tube 203 as a reaction tube is disposed inside the heater 206 to be concentric with the heater 206. The reaction tube 203 includes an inner tube 204 as an internal reaction tube (which may also be simply referred to as an internal tube) and an outer tube 205 as an external reaction tube (which may also be simply referred to as an external tube) provided outside of the inner tube. The inner tube 204 is made of a heat resistant material such as quartz (SiO₂) or silicon carbide (SiC) and is formed in a cylindrical shape with its upper and lower ends opened. A process chamber 201 is formed in a hollow portion of the inner tube 204 and is configured to accommodate wafers 200 in a state where the wafers 200 are vertically arranged in multiple stages in a horizontal posture by a boat 217 which will be described later. The outer tube 205 is made of a heat resistant material such as quartz or silicon carbide and has an inner diameter larger than an outer diameter of the inner tube 204. The outer tube 205 is formed in a cylindrical shape with its upper end closed and its lower end opened and is installed to be concentric with the inner tube 204.

A manifold 209 is disposed below the outer tube 205 to be concentric with the outer tube 205. The manifold 209 is made of, for example, stainless steel or the like and is formed in a cylindrical shape with its upper and lower ends opened. The manifold 209 engages with the inner tube 204 and the outer tube 205 to support them. An O-ring 220a as a sealer is installed between the manifold 209 and the outer tube 205. The manifold 209 is supported by the heater base 251 such that the reaction tube 203 is vertically installed. A reaction container is formed by the reaction tube 203 and the manifold 209.

A nozzle 230 as a gas introduction part is connected to a seal cap 219, which will be described later, to communicate with the process chamber 201, and a gas supply pipe 232 is connected to the nozzle 230. A process gas supply source or an inert gas supply source (not shown) is connected to an upstream side of the gas supply pipe 232, which is opposite to a connection side with the nozzle 230, via a mass flow controller (MFC) 241 as a gas flow rate controller. A gas flow rate controller 235 is electrically connected to the MFC 241 and is configured to control a flow rate of a supplied gas to a desired rate at a desired timing. Further, an opening/closing valve (for example, an air valve) (not shown) is provided on at least one of an upstream side and a downstream side of the MFC 241.

An exhaust pipe 231 for exhausting an atmosphere of the process chamber 201 is installed in the manifold 209. The exhaust pipe 231 is disposed at a lower end portion of a tubular space 250 formed by a gap between the inner tube 204 and the outer tube 205. The exhaust pipe 231 communicates with the tubular space 250. A vacuum exhaust device 246 such as a vacuum pump is connected to a downstream side of the exhaust pipe 231, which is opposite to a connection side with the manifold 209, via a pressure sensor 245 as a pressure detector and a pressure adjusting device 242, and is configured to vacuum-exhaust the process chamber 201 so that a pressure of the process chamber 201 becomes a predetermined pressure (degree of vacuum). A pressure controller 236 is electrically connected to the pressure adjusting device 242 and the pressure sensor 245, and is configured to control the pressure of the process chamber 201 to a desired pressure at a desired timing by the pressure adjusting device 242, based on a pressure detected by the pressure sensor 245.

The seal cap 219 as a lid that can air-tightly close the lower end opening of the manifold 209 is installed below the manifold 209. The lid 219 is in contact with the lower end of the manifold 209 from a lower side in a vertical direction. The lid 219 is made of metal such as stainless steel and is formed in a disc shape. An O-ring 220b as a sealer that comes into contact with the lower end of the manifold 209 is installed on an upper surface of the lid 219. A rotator 254 for rotating the boat is installed on a side of the lid 219 opposite to the process chamber 201. A rotary shaft 255 of the rotator 254 penetrates the lid 219 and is connected to the boat 217, which will be described later, and is configured to rotate the wafers 200 by rotating the boat 217. The lid 219 is configured to be vertically raised or lowered by a boat elevator 215 as an elevating mechanism vertically installed outside the reaction tube 203, whereby the boat 217 can be loaded/unloaded in/from the process chamber 201. A drive controller 237 is electrically connected to the rotator 254 and the boat elevator 215 and is configured to control the rotator 254 and the boat elevator 215 to perform a desired operation at a desired timing.

The boat 217 is made of a heat resistant material such as quartz or silicon carbide and is configured to support the plurality of wafers 200 in such a state that the wafers 200 are arranged in a horizontal posture and in multiple stages with the centers of the wafers 200 aligned with one another. A plurality of heat insulating plates 216 as disc-shaped heat insulators made of a heat resistant material such as quartz or silicon carbide are arranged in a horizontal position and in multiple stages below the boat 217, which leads to making it difficult for heat from the heater 206 to be delivered to the manifold 209.

A cascade thermocouple (a second temperature sensor) 263 as a temperature detector in the furnace is installed in the reaction tube 203. A heater thermocouple 264 (a first temperature sensor) is installed as a temperature detector for the heater 206. A temperature controller 238 is electrically connected to the heater 206, the heater thermocouple 264, and the cascade thermocouple 263. The temperature controller 238 is configured to control the process chamber 201 at a desired timing to have a desired temperature distribution by calculating a control target temperature of the heater 206 based on temperature information in the furnace detected by the cascade thermocouple 263 and adjusting a state of supplying electric power to the heater 206 based on the control target temperature and heater temperature information of the heater thermocouple 264.

The gas flow rate controller 235, the pressure controller 236, the drive controller 237, and the temperature controller 238 are electrically connected to a main controller 239 that controls the entire substrate processing apparatus. The gas flow rate controller 235, pressure controller 236, drive controller 237, temperature controller 238, and main controller 239 are configured as a controller 240.

Next, as a process of manufacturing a semiconductor device using the process furnace 202 according to the above configuration, a method of forming a film on wafers 200 will be described. In the following description, the operation of each of the parts constituting the substrate processing apparatus is controlled by the controller 240.

Once the plurality of wafers 200 are charged in the boat 217 (wafer charging), the boat 217 holding the plurality of wafers 200 is lifted up by the boat elevator 215 and is loaded in the process chamber 201 (boat loading), as shown in FIG. 1.

The process chamber 201 is vacuum-exhausted by the vacuum exhaust device 246 to have a desired pressure (vacuum degree). In this operation, the pressure of the process chamber 201 is measured by the pressure sensor 245, and the pressure adjusting device 242 is feedback-controlled based on the measured pressure. Further, the process chamber 201 is heated by the heater 206 so as to have a desired temperature. In this operation, the state of supplying electric power to the heater 206 is feedback-controlled based on the temperature information detected by the cascade thermocouple 263 so that the process chamber 201 has a desired temperature distribution. Subsequently, the rotator 254 rotates the boat 217 to rotate the wafers 200.

Next, a gas supplied from the process gas supply source and controlled to have a desired flow rate by the MFC 241 flows through the gas supply pipe 232 and is introduced into the process chamber 201 from the nozzle 230. The introduced gas goes up in the process chamber 201, flows out from an upper end opening of the inner tube 204 into the tubular space 250, and is exhausted through the exhaust pipe 231. When the gas passes through the process chamber 201, it comes into contact with surfaces of the wafers 200, at which time, for example, thin films are deposited on the surfaces of the wafers 200.

When a preset treatment time elapses, an inert gas is supplied from the inert gas supply source, the process chamber 201 is substituted with the inert gas, and the pressure of the process chamber 201 is returned to a normal pressure.

Subsequently, the seal cap 219 is lowered by the boat elevator 215 to open the lower end of the manifold 209, and the processed wafers 200 are unloaded from the lower end of the manifold 209 to the outside of the process tube 203 (boat unloading) while being held by the boat 217. After that, the processed wafers 200 are discharged from the boat 217 (wafer discharging).

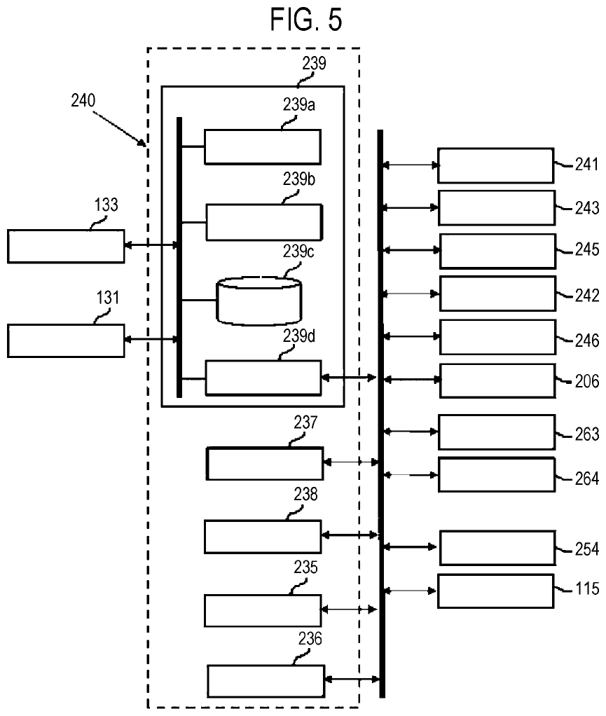

Next, as shown in FIG. 5, the controller 240 as a control part is connected to the gas flow rate controller 235, the pressure controller 236, the drive controller 237, the temperature controller 238, and the main controller 239 via a communication line. Here, the gas flow rate controller 235, the pressure controller 236, the drive controller 237, and the temperature controller 238 may have the same configuration as the main controller 239, and therefore, explanation thereof will be omitted, and the configuration of the main controller 239 will be described below.

The main controller 239 as a main control part is configured as a computer including a CPU (Central Processing Unit) 239a, a RAM (Random Access Memory) 239b, a memory 239c as a storage, and an I/O port 239d. The RAM 239b, the memory 239c, and the I/O port 239d are configured so as to be capable of exchange data with the CPU 239a via an internal bus. An input/output device 131 as an operation part composed of, for example, a touch panel or the like is connected to the controller 239.

The memory 239c is composed of, for example, a flash memory, a HDD (Hard Disk Drive), or the like. A control program for controlling the operation of the substrate processing apparatus, for example, a process recipe in which the procedures and conditions for substrate processing are written, and the like are readably stored in the memory 239c. The process recipe functions as a program for causing the controller 239 to execute each procedure in a substrate processing process, which will be described later, to obtain a predetermined result. Hereinafter, the process recipe and the control program may be generally and simply referred to as a “program.” The RAM 239b is configured as a memory area (work area) in which a program or data read by the CPU 239a is temporarily stored.

The I/O port 239d is connected to the above-mentioned MFC 241, valve (not shown), APC valve 242, pressure sensor 245, vacuum pump 246, heater 207, second temperature sensor 263, first temperature sensor 264, rotator 254, boat elevator 215, etc.

The CPU 239a is configured to read and execute the control program from the memory 293c. The CPU 239a also reads the process recipe from the memory 239c according to an input of an operation command from the operation part 131. The CPU 239a is configured to be capable of controlling the gas flow rate controller 235, the pressure controller 236, the drive controller 237, and the temperature controller 238 so as to control the flow rate adjustment operation of various kinds of gases by the MFC 241, the opening/closing operation of the valve 3 (not shown), the opening/closing operation of the APC valve 242, the pressure adjusting operation performed by the APC valve 243 based on the pressure sensor 245, the temperature adjustment operation performed by the heater 206 based on the second temperature sensor 263 and the first temperature sensor 264, the actuating and stopping of the vacuum pump 246, the operation of rotating the boat 217 with the rotator 254 and adjusting the rotation speed of the boat 217, the operation of lifting the boat 217 up or down by the boat elevator 215, and the like, according to contents of the read recipe. The details of the temperature adjustment operation of the heater 206 based on the second temperature sensor 263 and the first temperature sensor 264 by the temperature controller 238 will be described later.

The controller 239 is not limited to a case where it is configured as a dedicated computer, but may be configured as a general-purpose computer. For example, the controller 240 according to the present embodiment can be configured by installing the above-mentioned program on the general-purpose computer by using an external memory (for example, a semiconductor memory such as a USB memory) 133 as an external storage that stores the program.

How to supply the program to the computer is not limited to the case of supplying the program via the external memory 133. For example, a communication means such as the Internet or a dedicated line may be used to supply the program, instead of using the external memory 133. The memory 239c and the external memory 133 are configured as a non-transitory computer-readable recording medium. Hereinafter, the memory 239c and the external memory 133 are collectively and simply referred to as a “recording medium.” When the term “recording medium” is used herein, it may indicate a case of including the memory 239c only, a case of including the external memory 133 only, or a case of including both the memory 239c and the external memory 133.

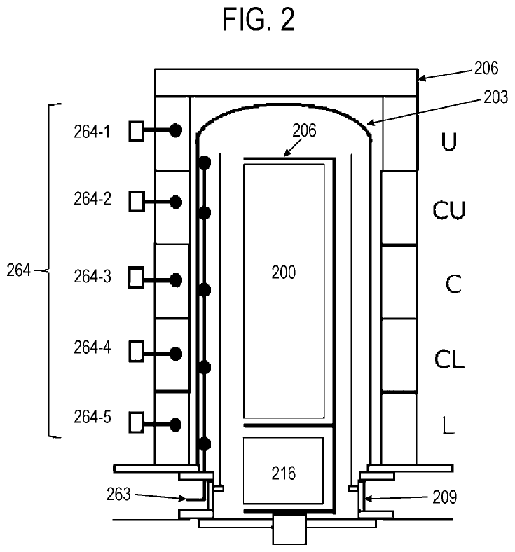

To explain the structure of the heater 206 of the present embodiment in detail with reference to FIG. 2, the heater 206 is provided in a plurality of heaters 206, which are piled up to control dividedly a plurality of zones (5 zones in FIG. 2) in the vertical direction. These are referred to as “heater zones (heating areas).” The “heater thermocouple” 264 for measuring the temperature of the heater 206 is installed in each heater zone. The “cascade thermocouple” 263 for measuring the internal temperature of the outer tube is installed inside the outer tube. The cascade thermocouple 263 has a structure in which multiple thermocouples (temperature sensors), which are the same number as that of heater zones, are accommodated in one quartz tube. A temperature measurement point of the cascade thermocouple 263 is installed at a position opposite to the heater zone. In FIG. 2, the heater 206 is divided into U, CU, C, CL, and L zones from its top. Further, the corresponding “heater thermocouples” are individually referred to as 264-1, 264-2, 264-3, 264-4, and 264-5 from the top, and are collectively referred to as the heater thermocouple 264.

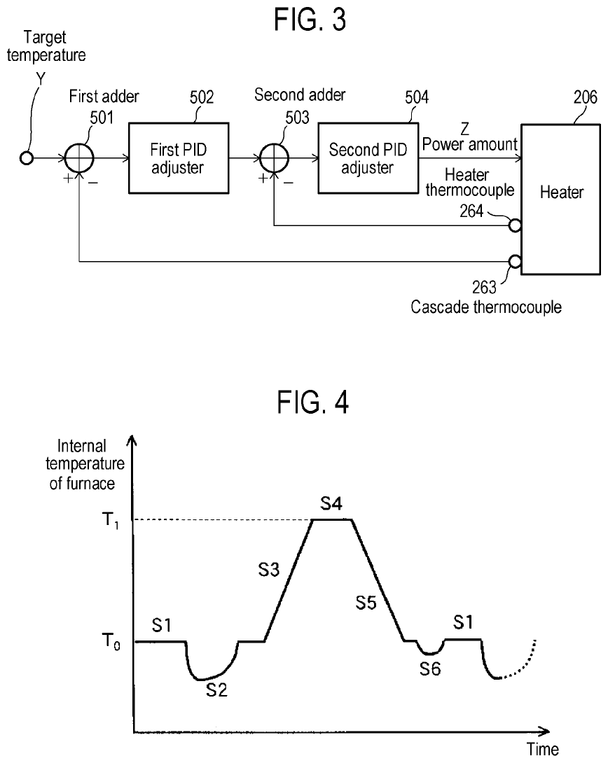

FIG. 3 is a configuration diagram of a temperature control system including the temperature controller 238 by a cascade control loop. FIG. 3 shows a so-called cascade PID control scheme in which the cascade control loop includes a “loop of a main temperature control part” that controls the temperature of the cascade thermocouple 263 for measuring the temperature of the vicinity of the wafer 200 in the process chamber 201 and a “loop of a heater temperature control part” that controls the temperature of the heater 206. The main temperature control part (a first PID adjuster) operates a set value in the heater temperature control part so that the temperature of the cascade thermocouple 263 matches a target value. The heater temperature control part (a second PID adjustier) operates a heater power output amount (described as a Z power amount in FIG. 3) so that the temperature of the heater thermocouple 264 matches a temperature set from the main temperature control part (the first PID adjusting part).

The cascade control loop shown in FIG. 3 includes a first adder 501 that outputs a deviation between a target temperature Y and a detection temperature from the cascade thermocouple 263; a first PID adjuster 502 that performs PID (Proportional, Integral, and Differentiation) calculation according to an output level of the first adder 501 and control to a value, which the detection temperature from the heater thermocouple 264 is to follow; a second adder 503 that outputs a deviation between an output level of the first PID adjuster 502 and a detection temperature from the heater thermocouple 264; and a second PID adjuster 504 that performs PID-calculation according to an output level of the second adder 503 and controls the amount of power Z supplied to the heater 206.

FIG. 3 shows a cascade control loop of one of the heater division zones (U, CU, C, CL, and L zones) in FIG. 2. When the heater 206 is divided into the five zones, a cascade control loop having the same configuration as in FIG. 3 exists for each zone. It is generally known that in this way, the detection temperature of the heater thermocouple 264, which has a relatively fast response speed, and the detection temperature of the cascade thermocouple 263, which has a relatively slow response speed, are used to form a cascade control loop as shown in FIG. 3, so that the detection temperature of the cascade thermocouple 263 can be quickly and stably controlled to the target temperature.

Next, a process sequence generally used in the process furnace 202 of FIG. 1 is described with reference to FIG. 4. FIG. 4 shows an outline of a temperature change in the process furnace 202 in each procedure of the process processing. Symbols S1 to S6 in FIG. 4 correspond to Procedures S1 to S6 of the process processing, respectively.

Procedure S1 is a process of stabilizing the internal temperature of the process furnace 202 at a relatively low temperature T₀. In procedure S1, the boat 217 has not yet been inserted into the reaction tube 203 in the process furnace 202. Procedure S2 is a process (boat loading) of inserting the boat 217 holding the wafer 200 into the reaction tube 203. Since the temperature of the wafer 200 is usually lower than the temperature T₀, as a result of inserting the boat 217 into the reaction tube 203, the internal temperature of the process furnace 202 temporarily becomes lower than T₀, but the internal temperature of the furnace is stabilized to the temperature T₀ again by the above-described temperature control after some time.

Procedure S3 is a process (ramp-up) of raising the internal temperature of the process furnace 202 from the temperature T₀ to a target temperature T₁ for performing a process such as film formation on the wafer 200. Procedure S4 is a process of maintaining and stabilizing the internal temperature of the process furnace 202 at the target temperature T₁ in order to process the wafer 200. Procedure S5 is a process (ramp-down) of lowering the internal temperature of the process furnace 202 from the target temperature T₁ to the relatively low temperature T₀ again after the process is completed. Procedure S6 is a process of drawing out the boat 217 on which the processed wafer 200 is mounted, from the process chamber 201. After that, the processed wafer 200 on the boat 217 is replaced with an unprocessed wafer 200. These serial processes (that is, procedures S1 to S6) are performed on all wafers 200.

Normally, since the processes of procedures S1 to S6 are repeated, each procedure is performed in a short time, which leads to improvement in productivity. In particular, since the temperature of the heater 206 is easy to heat and difficult to cool, how to shorten the time required for the ramp-down in procedure S5 is a key point for improving the productivity.

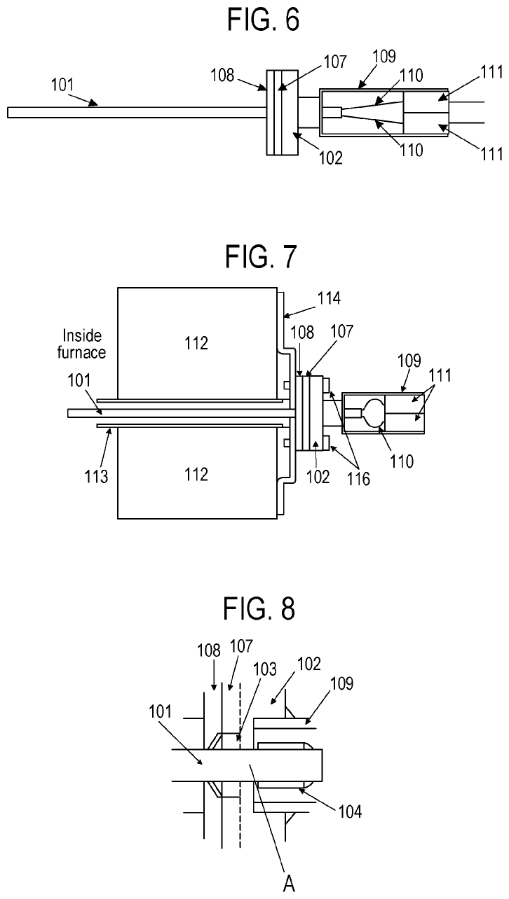

Hereinafter, the first temperature sensor 264 disposed in the vicinity of the heater 206 in the present embodiment is described with reference to FIGS. 6 to 10. The first temperature sensor 264 is provided in each of the five zones as shown in FIG. 2, but here, one first temperature sensor 264 is described for the sake of explanation.

As shown in FIG. 6, the first temperature sensor 264 includes a pipe having insulating property (insulating pipe) 101 as a main body made of alumina, which has a thermocouple wire 110 therein; a mount including a mounting plate made of SUS in which a flat plate-shaped opening hole (opening portion) for attaching the first temperature sensor 264 on the heater 206 is opened; a first heat insulator 107 and a second heat insulator 108 have cushioning properties, which will be described later, as cushions having excellent heat insulating property and airtightness (seal property); and a connection part connected to the temperature controller 238 (not shown).

The first temperature sensor 264 of the present embodiment has a structure in which the insulating pipe 101 is movable without a protective tube that was in the conventional heater thermocouple. Specifically, it is configured to be able to be moved up and down around a certain point (movable fulcrum) of the insulating pipe 101. This structure will be described later. Further, a slight gap (micro space) is provided between the opening hole of the mounting plate 102 and the insulating pipe 101. This micro space will also be described later. A leading end side (leading end portion) of the insulating pipe 101 is fixed by passing the thermocouple wire 110 through the insulating pipe 101, coupling leading ends of wires to form a temperature measuring part, and embedding and attaching the temperature measuring part in alumina cement so that the thermocouple wire 110 (temperature measuring part) is not exposed to the atmosphere of the furnace 202.

The connection part includes at least a cover 109 in which a tail end portion of the insulating pipe 101 is installed, and a connector 111 that outputs temperature data to the temperature controller 238 (not shown). In the cover 109, the thermocouple wire 110 protruding from the insulating pipe 101 (the end portion thereof) is connected to the connector 111. The thermocouple wire 110 up to the connector 111 is insulated by being covered with an insulator such as a polyimide tube. A sectional area of a portion of the cover 109 that surrounds the thermocouple wire 110 is configured to be larger than that of a portion of the cover 109 that surrounds the insulating pipe 101.

FIG. 7 shows a state in which the first temperature sensor 264 shown in FIG. 6 is attached to the process furnace 202, specifically, the heater 206. The insulating pipe 101 is installed not to come into contact with a ceramic cylindrical mounting pipe 113. Further, the insulating pipe 101 is installed to penetrate a heater cover panel (mounting panel) 114 as a panel made of SUS and a heat insulator 112, respectively, and a leading end portion of the insulating pipe 101 is installed inside the process furnace 202.

As the heat insulator 112 and the mounting pipe 113, those that can withstand a high processing temperature, for example, a high temperature of 1,000 degrees C. or higher in the processing furnace 202, are selected. The mounting pipe 113 also serves as a protective tube for the insulating pipe 101. The details will be described later. The mounting pipe 113 is installed to avoid contact between the leading end portion of the insulating pipe 101 and a heating element 115, which is useful for preventing damage to the insulating pipe 101.

When the first temperature sensor 264 is attached to the heater 206, a cushion is installed to fill a gap between the mounting panel 114 and the mounting plate 102. In particular, the cushion is installed by a double layer of the first heat insulator 107 and the second heat insulator 108. This is to improve the airtightness between the internal atmosphere of the furnace and outside air.

The first heat insulator 107 and the second heat insulator 108 are provided with through-holes in the central portions thereof through which the insulating pipe 101 passes, and are formed with holes at positions through which a fixture 116 as a screw for fixing the first temperature sensor 264 to the heater 206 passes.

The first heat insulator 107 is inserted from a side of the leading end of the insulating pipe 101, and then the second heat insulator 108 is similarly inserted from the side of the leading end of the main body 101. Then, the first temperature sensor 264 (the main body 101 thereof) in this state is inserted into the mounting pipe 113 from an outside of the mounting panel 114 to a position at which the first temperature sensor 264 comes into contact with the mounting panel 114, via the first heat insulator 107 and the second heat insulator 108. The mounting panel 114 is tapped, and the first temperature sensor 264 is attached to the heater 206 by fixing the mounting plate 102 with the fixture 116.

When the first heat insulator 107 and the second heat insulator 108 are inserted into the insulating pipe 101, an adhesive such as alumina cement is not used.

As will be described later, when the leading end of the insulating pipe 101 is pushed up, the insulating pipe 101 in the cover 109 goes down. Then, the thermocouple wire 110 goes down together with the insulating pipe 101. In consideration of this, as shown in FIG. 7, the thermocouple wire 110 is wired to be bent in advance where it is exposed from the insulating pipe 101 within the cover 109. Then, this bend absorbs a movement of the thermocouple wire 110.

The thermocouple wire 110 is a metal wire, and if it is bent greatly, it will have a bending tendency. Therefore, in FIG. 7, the thermocouple wire 110 from the insulating pipe 101 to the thermocouple connector 111 can be lengthened by bending the wiring of the thermocouple wire 110, which makes it possible for the first temperature sensor 264 to reduce the bending tendency when it moves.

The movable structure of the first temperature sensor 264 (the insulating pipe 101 thereof) is described with reference to FIG. 8. As shown in FIG. 8, the first temperature sensor 264 includes the insulating pipe 101 connected to the mounting plate 102 to penetrate the opening hole while providing the micro space (a gap smaller than 1 mm, for example, about 0.1 mm); a washer 103 as a first positioner made of ceramic in a cylindrical shape, which is formed on the side of the leading end portion of the insulating pipe 101 with respect to the mounting plate 102; and a spacer 104 as a second positioner 104 made of stainless steel in a cylindrical shape, which is formed on the side of the tail end of the insulating pipe 101 with respect to the mounting plate 102. The insulating pipe 101 is movable within a range determined by the micro space, the first positioner 103, and the second positioner 104. Specifically, the movement of the insulating pipe 101 can be restricted by the micro space, the first positioner 103, and the second positioner 104.

Due to such a configuration, a location where the mounting plate 102 and the insulating pipe 101 are connected to each other is connected by a portion A provided with an opening. Therefore, the insulating pipe 101 of the portion A inserted in the opening constitutes a fulcrum (movable fulcrum), so that the insulating pipe 101 can move up and down.

Here, the insulating pipe 101 and the washer 103, and the insulating pipe 101 and the spacer 104 are each fixed with an adhesive, for example, alumina cement. A portion of the insulating pipe 101 between the washer 103 and the spacer 104, which are attached to the insulating pipe 101, is configured to be inserted into the opening of the mounting plate 102.

A length between an end portion of the washer 103 on the side of the mounting plate 102 and an end portion of the spacer 104 on the side of the mounting plate 102 is greater than a width of the opening (a length of the opening in an axial direction of the insulating pipe 101). Further, a diameter of each portion to which the insulating pipe 101, the washer 103, and the spacer 104 are attached is greater than a diameter of the opening provided in the mounting plate 102.

The location where the mounting plate 102 and the insulating pipe 101 are connected to each other is connected by the portion where the opening is provided, and is adjusted so as to have the micro space between the mounting plate 102 and the insulating pipe 101. Further, the diameter and width of the opening hole are set to an appropriate diameter and width for securing a tilt range of the insulating pipe 101 when the insulating pipe 101 is tilted up and down, which will be described later.

According to the present embodiment, by making the diameter of the opening of the mounting plate 102 very small to form the micro space with respect to an outer diameter of the insulating pipe 101, the insulating pipe 101 of the portion A inserted in the opening forms a fulcrum (movable fulcrum), so that the insulating pipe 101 can move around this fulcrum. Therefore, the first temperature sensor 264 can measure a temperature in the vicinity of the heater 206 without being damaged even if the leading end portion of the insulating pipe 101 moves up and down.

Further, as described above, as the washer 103 and the spacer 104 are disposed on the insulating pipe 101 to sandwich the mounting plate 102 from the front and the back of the opening, the washer 103 and the spacer 104 serve as stoppers for preventing the insulating pipe 101 from moving in a thickness direction of the hole (the axial direction of the insulating pipe 101 in the opening). Further, this makes it possible for the insulating pipe 101 to move like a seesaw. Therefore, the first temperature sensor 264 can measure the temperature in the vicinity of the heater 206 without being damaged even if the leading end portion of the insulating pipe 101 moves up and down.

A part constituting the washer 103 is made of ceramic in consideration of heat resistance, and the spacer 104 is made of stainless steel to serve as a thin stopper. However, the materials and sizes of these parts are not particularly limited, and may be appropriately selected according to the conditions of use.

Further, when the washer 103 and the spacer 104 are fixed to the insulating pipe 101 with an adhesive, it is preferable to use more adhesive on sides opposite to the mounting plate 102. This is because there is a possibility that the first temperature sensor 264 cannot be moved if an adhesive fills and closes the micro space provided between the opening of the mounting plate 102 and a portion of the insulating pipe 101 inserted into the opening, which makes it possible for the first temperature sensor 264 to be moved with the portion of the insulating pipe 101 inserted into the opening as a movable fulcrum. Further, if the insulating pipe 101 and the mounting plate 102 are fixed by the adhesive, the first temperature sensor 264 may not be movable.

Further, the mounting plate 102 and the cover 109 are attached to each other by welding so that the cover 109 is inserted into the mounting plate 102. The spacer 104 is installed inside the cover 109.

The washer 103 is covered with the first heat insulator 107, the washer 103 and the first heat insulator 107 are in close contact with the mounting plate 102, and the second heat insulator 108 is installed to cover the insulating pipe 101 to be in close contact with the first heat insulator 107. Specifically, the first heat insulator 107, whose center may be penetrated by the washer 103, is installed at an inner side to the process furnace 202 with respect to the opening of the mounting plate 102. The second heat insulator 108, whose center may be penetrated by the insulating pipe 101, is installed in close contact with the first heat insulator 107 at an inner side to the process furnace 202 with respect to the first heat insulator 107. As a result, a doubled heat insulator is installed and the airtightness between the internal atmosphere of the process furnace 202 and the outside of the mounting plate 102 is secured. Since the mounting panel 114 communicates with an interior of the process furnace 202 via the mounting pipe 113, a flexible member that is great in terms of durability and airtightness even at a high temperature and does not interfere with the movement of the first temperature sensor 264 (the main body 101 thereof) is selected for the first heat insulator 107 and the second heat insulator 108.

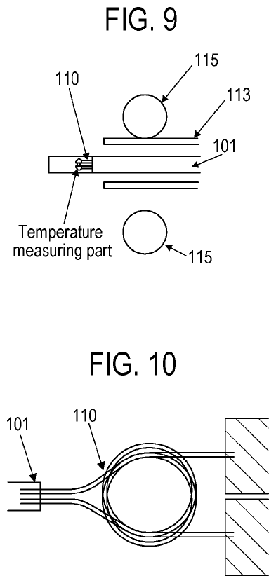

The leading end portion of the first temperature sensor 264 (the insulating pipe 101) is described with reference to FIG. 9. The thermocouple wire 110 and the temperature measuring part shown in FIG. 9 are not exposed from the insulating pipe 101 due to alumina cement, but are shown for the sake of explanation.

If an amount of protrusion of the insulating pipe 101 from the heat insulator 112 is small, the influence of the heat insulator 112 becomes large to lower the responsiveness. In addition, a temperature difference from the heating element 115 as a heater also becomes large.

Therefore, as shown in FIG. 9, the thermocouple wire 110 is installed inside the insulating pipe 101, and the temperature measuring part is installed at the leading end portion of the insulating pipe 101. The leading end portion including the temperature measuring part is disposed at an inner side of the process furnace 202 with respect to the heating element 115 of the heater 206. For example, the leading end of the insulating pipe 101 is disposed in the vicinity of the reaction tube 203. As a result, the insulating pipe 101 is disposed in the inner side of the process furnace 202 with respect to the heating element 115 within a range that does not interfere with the reaction tube 203, thereby ensuring an amount of protrusion of the heat insulator 112 of the insulating pipe 101 and accordingly detecting a temperature close to the temperature of the heating element 115 with good responsiveness.

The mounting pipe 113 is also disposed in the inner side of the process furnace 202 with respect to the heating element 115, like the insulating pipe 101. The heating element 115 may move to the inner side of the process furnace 202 due to plastic deformation when the heating element 115 is used for a long period of time. Therefore, the mounting pipe 113 is installed to extend to the inner side of the process furnace 202 with respect to the heating element 115. As a result, it is possible to reduce the interference between the heating element 115 and the insulating pipe 101 by the mounting pipe 113, and accordingly it is possible to suppress damage to the first temperature sensor 264.

FIG. 10 is a detailed view of the tail end portion of the main body, showing an example in which the wiring of the thermocouple wire 110 protruding from the tail end portion of the insulating pipe 101 is further devised. In FIG. 10, the thermocouple wire 110 protruding from the insulating pipe 101 is configured to be wound around at least one turn, like a spiral shape, and then to be connected to the connector 111.

In the configuration shown in FIG. 10, when the tail end portion of the insulating pipe 101 goes down, a distance between an outlet of the insulating pipe 101 and the connector 111 is increased, thereby a spiral portion is tightened by that amount and the spiral portion is moved downward. Therefore, a bending angle of the thermocouple wire 110 at the tail end portion of the insulating pipe 101 becomes smaller.

As a result, since a bending stress related to the thermocouple wire 110 due to the movement of the first temperature sensor 264 is small, it is possible to suppress disconnection of the thermocouple wire 110, which can lead to a longer life of the thermocouple wire 110.

As shown in FIG. 7, the thermocouple wire 110 protruding from the tail end portion of the insulating pipe 101 is bent, but if the thermocouple wire 110 at the outlet of the insulating pipe 101 has a bending tendency when the internal temperature of the furnace is high, the leading end of the main body 101 will not return to its original position when the internal temperature of the furnace drops. Then, the insulating pipe 101 and an upper surface of the mounting pipe 113 may come into contact with each other and be damaged.

Further, a pressure is applied from the mounting pipe 113 when the insulating pipe 101 and the upper surface of the mounting pipe 113 come into contact with each other, and thus, when the insulating pipe 101 returns to its original position to some extent, there is a possibility of disconnection of the thermocouple wire 110 by receiving a tensile stress.

Therefore, according to the device disclosed in FIG. 10, as the thermocouple wire 110 protruding from the insulating pipe 101 is wired in a spiral shape to reduce the degree of bending tendency of the thermocouple wire 110, the insulating pipe 101 also returns to its original position together with the mounting pipe 113. In this way, it is possible to avoid contact between the insulating pipe 101 and the mounting pipe 113 when the internal temperature of the furnace is lowered.

In this way, according to the configuration shown in FIG. 10, there is no risk of damage to the first temperature sensor 264 and disconnection of the thermocouple wire 110 due to the bending tendency of the thermocouple wire 110.

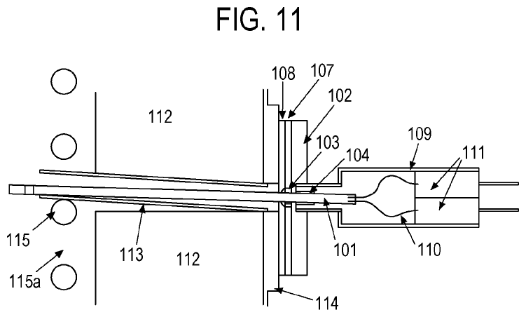

FIG. 11 shows the first temperature sensor 264 at temperature T₁ (procedure S4) while a process is performed in individual procedures (S1 to S6) shown in FIG. 4. The same elements as those in FIG. 7 may be omitted for the sake of avoiding repeated explanations.

The heater 206 includes the heat insulator 112 that constitutes the heater main body, the heating element 115 provided in the vicinity of the heat insulator 112, the ceramic mounting pipe 113 provided to penetrate the heat insulator 112, and the mounting panel 114 made of SUS for attaching the first temperature sensor 264. The heat insulator 112 constitutes, for example, a laminated structure formed by laminating heat insulators. Further, a case made of SUS is attached to surround the heat insulator 112, and the mounting panel 114 is provided to this case.

The heating element 115 moves upward when the internal temperature T₁ of the furnace rises. Then, with this movement, the mounting pipe 113 is pushed up. Since the heat insulator 112 is more flexible than the mounting pipe 113, the mounting pipe 113 pushed up by the heating element 115 is inserted into the upper heat insulator 112. The pushed-up mounting pipe 113 pushes up the insulating pipe 101 while being in contact with the insulating pipe 101. As a result, the side of the leading end of the insulating pipe 101 moves upward. At this time, the heating element 115 and the insulating pipe 101 do not come into direct contact with each other due to the mounting pipe 113.

The insulating pipe 101 moves within a range limited by the washer 103 and the spacer 104 attached to the insulating pipe 101. Here, the insulating pipe 101 is usually supported by a portion inserted into the opening of the mounting plate 102, and is configured to tilt like a seesaw with this portion as a movable fulcrum. In this case, since the side of the leading end of the insulating pipe 101 moves upward, the side of the tail end of the insulating pipe 101 is configured to be tilt downward. In this way, the insulating pipe 101 moves according to thermal expansion of movement of the parts (including the heat insulator 112, the mounting pipe 113, and the heating element 115) constituting the heater unit, which results in not damaging the insulating pipe 101.

Further, since the first heat insulator 107 and the second heat insulator 108 installed to cover the periphery of the insulating pipe 101 have cushioning properties, they do not hinder the movement of the insulating pipe 101.

The tail end portion of the insulating pipe 101 tilts downward, and the thermocouple wire 110, which extends from the tail end portion, moves downward, but the act of the insulating pipe 101 is not interfered since the thermocouple wire 110 is wired to be bent. That is, the length of the thermocouple wire 110 can be extended by giving the thermocouple wire 110 the bend. As a result, a stress associated with the act of the insulating pipe 101 is reduced so as to suppress the disconnection of the thermocouple wire 110.

As described above, even if the internal temperature T₁ of the furnace is high and the parts constituting the heater unit move due to thermal expansion, the first temperature sensor 264 is not damaged and it is possible to measure the internal temperature of the process furnace 202 when the wafer 200 is being processed in procedure S4.

Here, since the connector 111 is connected to the temperature controller 238 (not shown), a temperature detection value is output to the temperature controller 238, and the temperature controller 238 is configured to be able to control the temperature by, for example, the feedback control shown in FIG. 3.

Then, procedure S4 is completed and the internal temperature of the furnace drops (for example, to the temperature T₀), the heating element 115 that has moved upward due to the thermal expansion goes down to return to its original position 115a when the internal temperature of the process furnace 202 drops. Then, the tilted mounting pipe 113 also returns to its original position, and the insulating pipe 101 also returns to its original position together with the mounting pipe 113 so as to avoid the contact between the insulating pipe 101 and the mounting pipe 113.

As described above, according to the present embodiment, at least one of the following (a) to (k) is achieved.

(a) According to the present embodiment, by inserting the insulating pipe 101 into the opening hole provided in the mounting plate 102 to penetrate the heater thermocouple 264, the insulating pipe 101 is supported by the opening hole of the mounting plate 102 and it is not fixed to the mounting plate 102 which would have prevented the insulating pipe 101 from moving if it were fixed to the mounting plate. As a result, even if the side of the leading end of the insulating pipe 101 moves up and down, the insulating pipe 101 can be tilted around a portion of the insulating pipe 101 that corresponds to the opening hole. Therefore, the risk of damage to the heater thermocouple 264 can be reduced.

(b) According to the present embodiment, by providing the washer 103 at an inside of the process furnace 202 and the spacer 104 at an outside of the process furnace 202, with respect to a boundary which is a portion where the insulating pipe 101 is connected to the mounting plate 102, it is possible to limit the movable range of the insulating pipe 101 when the side of the leading end of the insulating pipe 101 moves up and down and tilts around the portion of the insulating pipe 101, which corresponds to the opening hole.

(c) According to the present embodiment, a cushion 107 whose center may be penetrated by the washer 103 at an inner side to the process furnace 202 with respect to the opening of the mounting plate 102, and a cushion 108 whose center may be penetrated by the insulating pipe 101 at an inner side to the process furnace 202 with respect to the cushion 107 are installed as a double structure. As a result, the airtightness between the internal atmosphere of the process furnace 202 and the mounting plate 102 is secured.

(d) According to the present embodiment, since the insulating pipe 101, the washer 103, and the spacer 104 are not fixed to the mounting plate 102 which would have prevented the insulating pipe 101 from moving if it were fixed to the mounting plate, the side of the leading end of the insulating pipe 101 is not prevented from being tilted around the portion of the insulating pipe 101, which corresponds to the opening hole, by moving up and down. Therefore, the risk of damage to the heater thermocouple 264 can be reduced.

(e) According to the present embodiment, since the thermocouple wire 110 is connected to the connector 111 with an increased length of the thermocouple wire 110 with respect to the distance from the insulating pipe 101 to the connector 111, for example, the thermocouple wire 110 protruding from the tail end of the insulating pipe 101 is allowed to have a bend, it is possible to absorb a thermal stress, for example, a tensile stress, of the thermocouple wire 110 due to thermal expansion by the tilt of the insulating pipe 101. This makes it possible to prevent the thermocouple wire 110 from being disconnected.

(f) According to the present embodiment, when the thermocouple wire 110 protruding from the tail end of the insulating pipe 101 is wired in a spiral shape and connected to the connector 111, the length of the thermocouple wire 110 becomes large to absorb the thermal stress of the thermocouple wire 110 by the tilt of the insulating pipe 101, and also absorb the thermal stress by the vertical movement of the spiral-shaped thermocouple wire 110. As a result, the degree of bending tendency of the thermocouple wire 110 is reduced to further reduce the risk of damage to the thermocouple wire 110.

(g) According to the present embodiment, as the thermocouple wire 110 protruding from the tail end of the insulating pipe 101 is wired in a spiral shape to reduce the degree of bending tendency of the thermocouple wire 110, since the leading end portion of the insulating pipe 101 moves up during the processing of the wafer 200 and the insulating pipe 101 returns to its original position when the processing of the wafer 200 is completed, the risk of disconnection of the thermocouple wire 110 can be reduced.

(h) According to the present embodiment, the heater thermocouple 264 is attached with respect to the heater 206 such that heater thermocouple 264 is inserted into the ceramic pipe 113 that is provided to penetrate the heat insulator 112. As a result, since the leading end of the insulating pipe 101 does not come into direct contact with the heating element 315, the risk of damage to the heater thermocouple 264 can be reduced.

(i) According to the present embodiment, since the temperature measuring part for measuring a temperature is provided at the leading end portion of the insulating pipe 101 of the heater thermocouple 264 and the leading end of the insulating pipe 101 extends to the vicinity of the reaction tube 203, the internal temperature of the process furnace 202 can be measured.

(j) According to the present embodiment, even when the internal temperature of the process furnace 202 becomes high and the parts (for example, the ceramic pipe 113 and the heating element 115) constituting the heater 206 move (in this case, upward) due to thermal expansion, since the heater thermocouple 264 has a movable structure, the risk of damage of the heater thermocouple 264 can be suppressed to a low level.

(k) According to the present embodiment, when the temperature of the parts (for example, the ceramic pipe 113 and the heating element 115) constituting the heater 206 moved by thermal expansion becomes low (e.g., the temperature T₀) after completing the processing of the wafer 200, for example, these parts return to their original positions and the heater thermocouple 264 also returns to its original position. In this way, since the heater thermocouple 264 has a movable structure, the risk of damage of the heater thermocouple 264 can be suppressed to a low level.

According to the present disclosure in some embodiments, it is possible to measure a temperature in the vicinity of a heater regardless of the temperature of the heater.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A temperature sensor installed on a mount provided with an opening, comprising:
a main body connected to the mount to penetrate the opening while providing a micro space;
a first positioner attached to a side of a leading end portion of the main body with respect to the mount; and
a second positioner attached to a side of a tail end portion of the main body with respect to the mount,
wherein the main body is movable within a range determined by the micro space, the first positioner, and the second positioner.

2. The temperature sensor of claim 1, wherein a portion of the main body, which is between a portion of the main body to which the first positioner is attached and a portion of the main body to which the second positioner is attached, is inserted into the opening.

3. The temperature sensor of claim 1, wherein a length between an end portion of the first positioner at a side of the mount and an end portion of the second positioner at a side of the mount is larger than a length of the opening in an axial direction of the main body.

4. The temperature sensor of claim 1, wherein a diameter of each portion, at which the main body, the first positioner and the second positioner are attached, is larger than a diameter of the opening provided in the mount.

5. The temperature sensor of claim 1, further comprising a first heat insulator installed to cover the first positioner,
wherein the first positioner and the first heat insulator are in close contact with the mount.

6. The temperature sensor of claim 5, further comprising a second heat insulator installed to be in close contact with the first heat insulator and to cover the main body.

7. The temperature sensor of claim 1, wherein each of the main body, the first positioner, and the second positioner is configured not to be fixed to the mount by an adhesive.

8. The temperature sensor of claim 5, wherein each of the main body, the first positioner, and the mount is configured not to be fixed to the first heat insulator by an adhesive.

9. The temperature sensor of claim 5, wherein each of the main body and the first positioner is configured not to be fixed to the first heat insulator by an adhesive.

10. The temperature sensor of claim 1, further comprising a connection part including a cover containing at least the tail end portion of the main body therein and a connector, wherein a wire protruding from the tail end portion is configured to be covered with an insulator.

11. The temperature sensor of claim 10, wherein a wiring of the wire from the tail end portion to the connector is configured to include a bend.

12. The temperature sensor of claim 10, wherein the wire from the tail end portion to the connector is configured to be wired in a spiral shape.

13. The temperature sensor of claim 1, further comprising a wire constituting a temperature measuring part in an interior of the main body, and
wherein the temperature measuring part is installed at a leading end of the main body.

14. A heater unit comprising:
a temperature sensor installed on a mount provided with an opening,
wherein the temperature sensor includes:
a main body connected to the mount to penetrate the opening while providing a micro space;
a first positioner attached to a side of a leading end portion of the main body with respect to the mount; and
a second positioner attached to a side of a tail end portion of the main body with respect to the mount, and
wherein the temperature sensor is configured to be capable of restricting movement of the main body by the micro space, the first positioner, and the second positioner.

15. A substrate processing apparatus comprising:
a heater unit including a temperature sensor installed on a mount provided with an opening,
wherein the temperature sensor includes:
a main body connected to the mount to penetrate the opening while providing a micro space;
a first positioner attached to a side of a leading end portion of the main body with respect to the mount; and
a second positioner attached to a side of a tail end portion of the main body with respect to the mount, and
wherein the temperature sensor is configured to be capable of restricting movement of the main body by the micro space, the first positioner, and the second positioner.
